(19) United States
(12) Patent Application Publication
(10) Pub. No.: US 2026/0305041 A1
(43) Pub. Date: Oct. 1, 2026

(54) DISPLAY DEVICE

(71) Applicant: LG Display Co., Ltd., Seoul (KR)

(72) Inventors: HongMan MOON, Goyang-si (KR); Byeong-Ryeol SEO, Gumi-si (KR)

(21) Appl. No.: 19/423,472

(22) Filed: Dec. 17, 2025

(30) Foreign Application Priority Data
Mar. 31, 2025 (KR) 10-2025-0041611

(51) Int. Cl. H10H 29/855; H10H 20/831; H10H 29/37

(52) U.S. Cl. CPC H10H 29/8552; H10H 20/831; H10H 29/37

(57) ABSTRACT

A display device including a substrate, a first electrode disposed on the substrate and including an inclined surface, a light emitting element including a light emitting layer and a second electrode, a bank disposed on the first electrode and defining an emission area by exposing the inclined surface, a black matrix disposed on the bank and including a first opening overlapping the emission area, a barrier layer disposed on the black matrix and including a second opening overlapping the first opening, and an optical member disposed on the second opening.

### CROSS REFERENCE TO RELATED APPLICATION

This application claims priority from and the benefit of Korean Patent Application No. 10-2025-0041611, filed on Mar. 31, 2025, which is hereby incorporated by reference for all purposes as if fully set forth herein.

### BACKGROUND

### FIELD

Embodiments of the invention relate generally to a display device, and more particularly, without limitation, to a display device in which a dual view display is implemented.

### DISCUSSION OF THE BACKGROUND

With the development of technologies in modern society, display devices are being used in various ways to provide information to users. Display devices are included in electronic signs that simply transmit visual information in one direction, as well as in various electronic devices that require higher technology to detect a user's input and provide information in response to the detected input.

For example, the display device may be included in a vehicle to provide different information to a driver and a passenger of the vehicle.

The above information disclosed in this Background section is only for understanding of the background of the inventive concepts, and, therefore, it may contain information that does not constitute prior art.

### SUMMARY

Embodiments of the invention provide a display device which suppresses deterioration in luminance depending on a viewing angle and improves luminous efficiency.

Embodiments of the invention provide a display device capable of viewing an optimal image at each viewing angle position when viewing images at different viewing angles.

Additional features of the inventive concepts will be set forth in the description which follows, and in part will be apparent from the description, or may be learned by practice of the inventive concepts.

According to an embodiment of the invention, a display device includes a substrate, a first electrode disposed on the substrate and ahving an inclined surface, a light emitting element including a light emitting layer and a second electrode, a bank disposed on the first electrode and defining an emission area of the light emitting element by exposing the inclined surface, a black matrix disposed on the bank and including a first opening at least partially overlapping the emission area, a barrier layer disposed on the black matrix and including a second opening at least partially overlapping the first opening, and an optical member disposed on the second opening.

The center of the emission area may be shifted in a first direction with respect to the center of the optical member.

The height of the inclined surface may be lowered toward a second direction opposite to the first direction.

One end of the first opening may protrude from one end of the emission area toward the inside of the emission area.

One end of the first opening may coincide with one end of the emission area.

One end of the second opening may protrude further toward the center of the optical member than one end of the first opening.

The display device may further include a planarization layer disposed on the substrate, and a protrusion disposed on the planarization layer. An emission area may be disposed on the protrusion.

The barrier layer may include an opaque metal material.

A size of the first opening may be equal to or greater than that of the second opening.

A display device according to another embodiment of the invention includes a substrate, a plurality of light emitting elements which is disposed on the substrate and includes an emission area having an inclined surface, a black matrix which is disposed on the plurality of light emitting elements and includes a plurality of first openings corresponding to the emission areas of the plurality of light emitting elements, a barrier layer which is disposed on the black matrix and includes a plurality of second openings which at least partially overlaps the plurality of first openings, and a plurality of optical members which is disposed on the plurality of second openings, the plurality of light emitting elements includes a first group of light emitting elements having the inclined surface inclined in a second direction, and a second group of light emitting elements having the inclined surface inclined in the first direction different from the second direction.

The first direction and the second direction may be opposite directions.

The center of each of the first group of light emitting element may be shifted in the first direction with respect to the center of a corresponding optical member among the plurality of optical members, and the center of each of the second group of light emitting element may be shifted in the second direction with respect to the center of a corresponding optical member among the plurality of optical members.

The first group of light emitting element and the second group of light emitting element may be alternately disposed in the third direction orthogonal to the first direction on a plane.

The plurality of optical members may include a first optical member at least partially overlapping the first group of light emitting elements and a second optical member at least partially overlapping the second group of light emitting elements, and the first optical member and the second optical member may be disposed in a zigzag pattern in the third direction.

The display device may further include a planarization layer disposed on the substrate, and a plurality of protrusions disposed on the planarization layer. An emission area of each of the plurality of light emitting elements may be disposed on the plurality of protrusions.

One end of the plurality of second openings may protrude further toward the center of the plurality of optical members than one end of the plurality of first openings.

One end of the plurality of first openings may coincide with one end of the emission area.

One end of the plurality of first openings may protrude inside the emission area.

A display device according to another embodiment of the invention may include a substrate; a light emitting element disposed on the substrate and including a first electrode having an inclined surface, a light emitting layer, and a second electrode; a bank disposed on the first electrode and exposing the inclined surface to define an emission area of the light emitting element; and an optical member disposed over the bank and at least partially overlapping with the emission area, in which the center of the emission area is shifted in a first direction with respect to the center of the optical member, and in which a height of the inclined surface decreases toward a second direction opposite to the first direction.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a perspective view of a display device according to an embodiment of the invention.

FIG. 2 is a functional block diagram of a display device according to an embodiment of the invention.

FIG. 3 is an enlarged plan view illustrating an arrangement of sub-pixels according to an embodiment of the invention.

FIG. 4 is a cross-sectional view taken along line A-A' of the display device of FIG. 3.

FIG. 5 is a cross-sectional view taken along line B-B' of the display device of FIG. 3.

FIG. 6 is a cross-sectional view of a display device according to another embodiment of the invention.

FIG. 7 is a cross-sectional view of a display device according to another embodiment of the invention.

FIG. 8 is a simulation result that compares luminance changes according to a viewing angle of comparative embodiments and embodiments of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

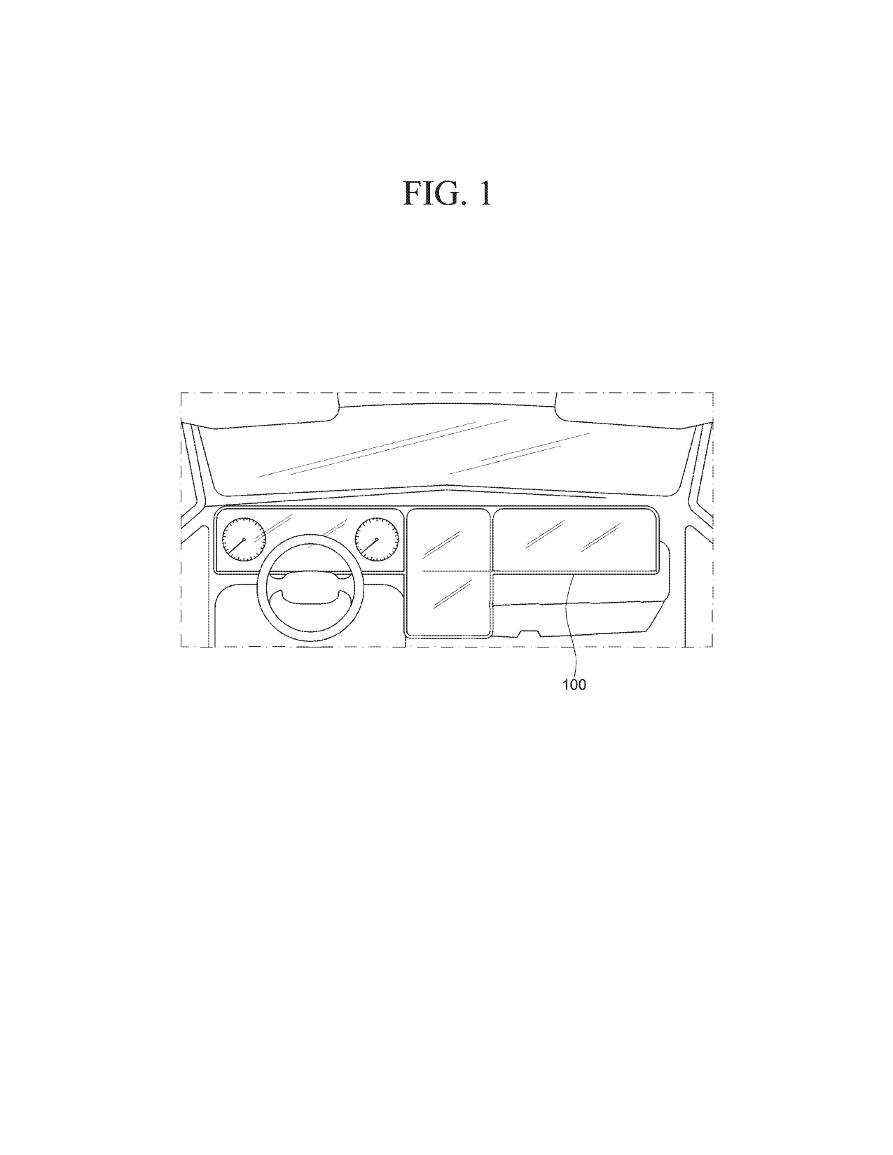

FIG. 1 is a perspective view of a display device according to an embodiment of the invention.

Referring to FIG. 1, a display device 100 according to an embodiment may be disposed on at least a portion of a dashboard of a vehicle, however, the inventive concepts are not limited thereto. In some embodiments, the display device may alternatively be disposed on another position of any electronic devices including, but not limited to, the vehicle. The dashboard of the vehicle may include a configuration disposed in front of front seats of the vehicle. For example, an input configuration for manipulating various functions inside the vehicle such as an air conditioner, an audio system, and a navigation system may also be disposed on the dashboard of the vehicle, but is not limited thereto.

The display device 100 may be disposed on the dashboard of the vehicle and may function as an input unit for manipulating at least some of various functions of the vehicle. The display device 100 may provide various information related to the vehicle, including driving information of the vehicle such as a current speed of the vehicle, a remaining fuel amount or battery remaining capacity, and a driving distance, and further including information on parts of the vehicle such as a damage degree of a vehicle tire, without being limited thereto.

The display device 100 may be disposed across the driver seat and the passenger seat of the vehicle. The user of the display device 100 may include a driver of the vehicle and a passenger riding in the passenger seat. Both the driver and the passenger of the vehicle may use the display device 100.

FIG. 1 illustrates only a portion of the display device 100 as an example. The display device 100 may represent a display panel among various configurations included in the display device 100. For example, the display device 100 illustrated in FIG. 1 may represent at least a part of a display area and a non-display area of a display panel. Among the configurations of the display device 100, configurations other than those illustrated in FIG. 1 may be mounted inside or at least within a portion of the vehicle.

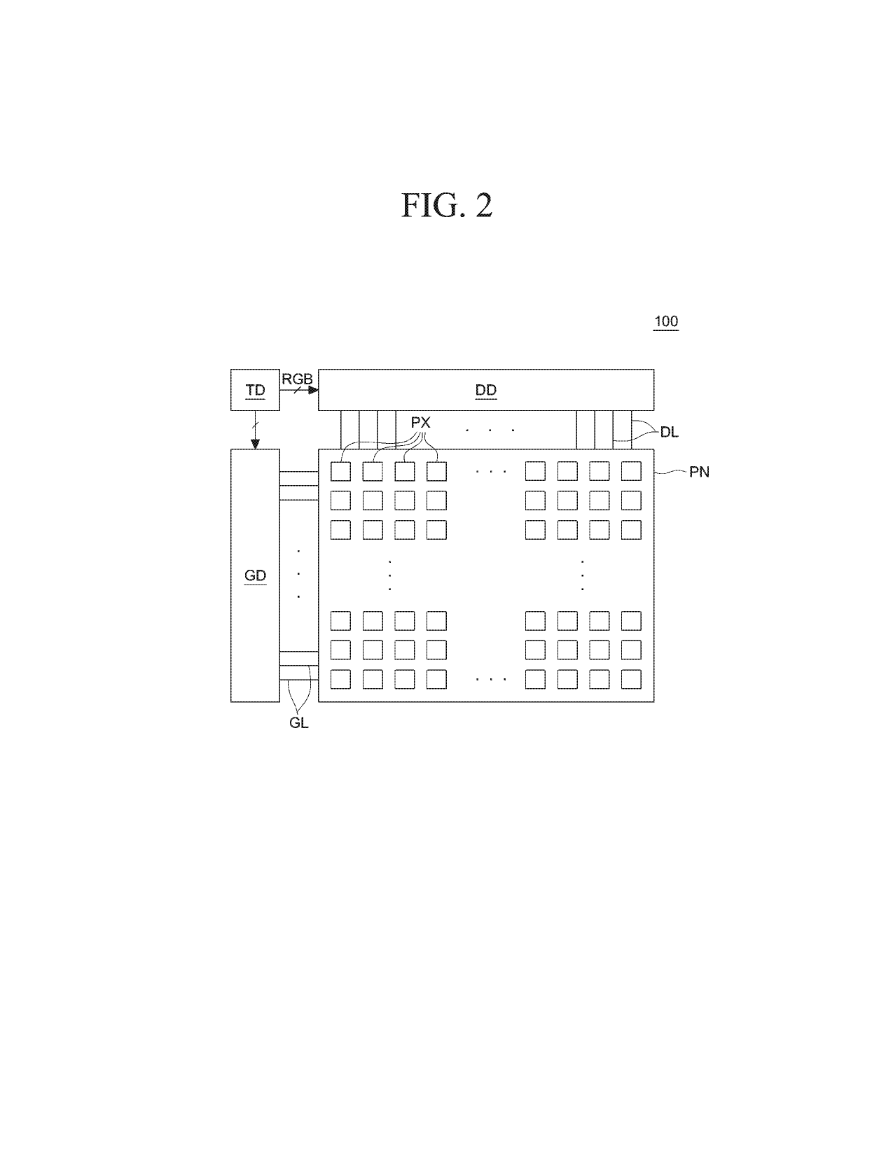

FIG. 2 is a functional block diagram of a display device 100 according to an embodiment of the invention.

An electroluminescent display device may be applied to a display device according to an embodiment of the invention. However, the inventive concepts are not limited thereto, and a display device may include various other types of display devices such as LCD display device or plasma display device. The electroluminescent display device may be an organic light emitting diode display device, a quantum-dot light emitting diode display device, or an inorganic light emitting diode display device, without being limited thereto.

Referring to FIG. 2, the display device 100 may include a display panel PN, a data driving circuit DD, a gate driving circuit GD, and a timing controller TD.

The display panel PN may generate an image to be provided to the user. For example, the display panel PN may generate and display an image to be provided to the user through a plurality of pixels PX in which pixel circuits are disposed.

The data driving circuit DD, the gate driving circuit GD, and the timing controller TD may provide signals for the operation of each pixel PX through signal lines. For example, the signal lines for providing the signals for the operation of each pixel PX may include a plurality of data lines DL and a plurality of gate lines GL.

The plurality of data lines DL may include a plurality of lines arranged in a column direction and electrically connected to pixels PX arranged in one column direction, and the plurality of gate lines GL may include a plurality of lines arranged in a row direction and electrically connected to pixels PX arranged in one row direction.

For example, the data driving circuit DD may apply a data signal to each pixel PX through a plurality of data lines DL, the gate driving circuit GD may apply a gate signal to each pixel PX through a plurality of gate lines GL, and the power unit may supply a power voltage to each pixel PX through a power voltage supply line.

The timing controller TD may control the data driving circuit DD and the gate driving circuit GD. For example, the timing controller TD may rearrange digital video data input from the outside to match the resolution of the display panel PN and supply the rearranged digital video data to the data driving circuit DD.

The data driving circuit DD may convert digital video data input from the timing controller TD into an analog data voltage based on a data control signal, and supply the analog data voltage to the plurality of data lines DL.

The gate driving circuit GD may generate gate signals such as a scan signal and an emission signal based on the gate control signal. For example, the gate driving circuit GD may include a scan driver and an emission signal driver. The scan driver generates a scan signal in a row sequential manner to drive at least one scan line electrically connected to each pixel row and may supply the scan signal to the scan lines. The emission signal driver generates an emission signal in a row sequential manner to drive at least one emission signal line electrically connected to each pixel row to supply the emission signal to the emission signal lines.

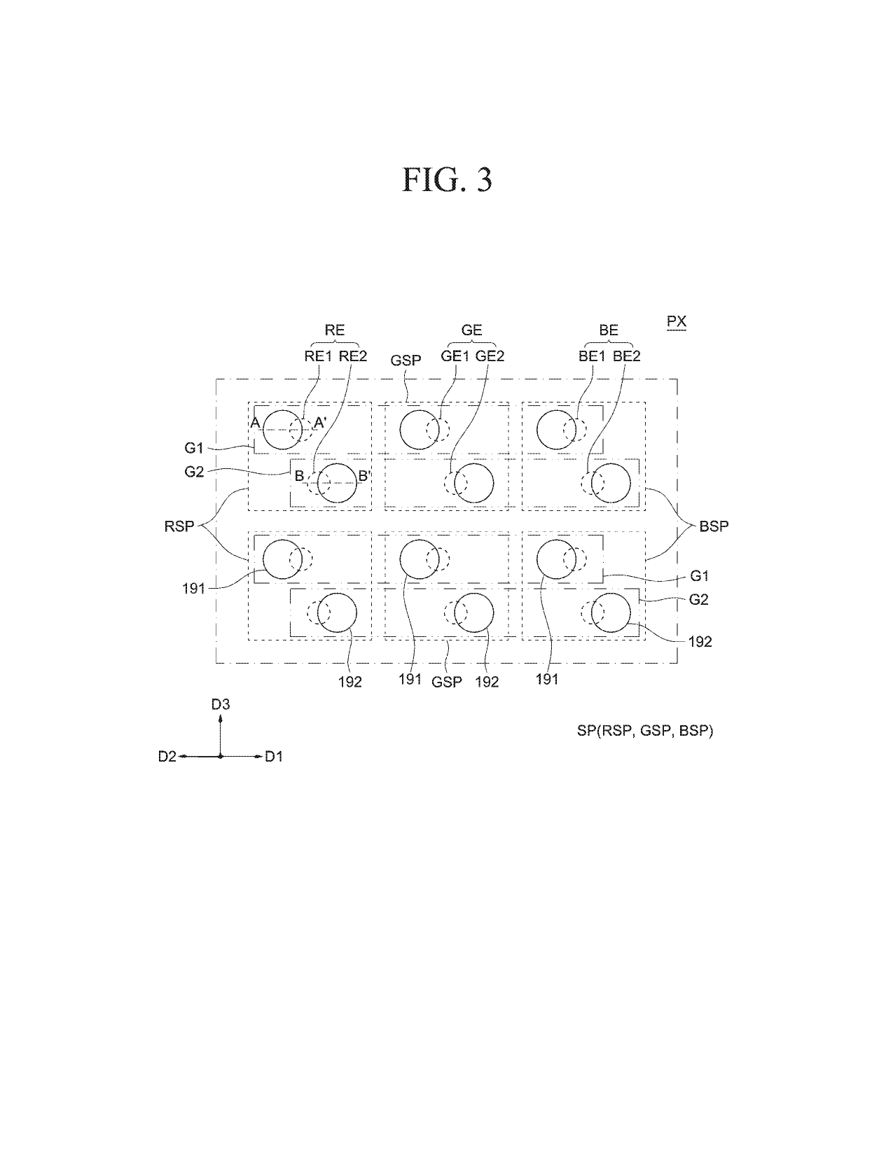

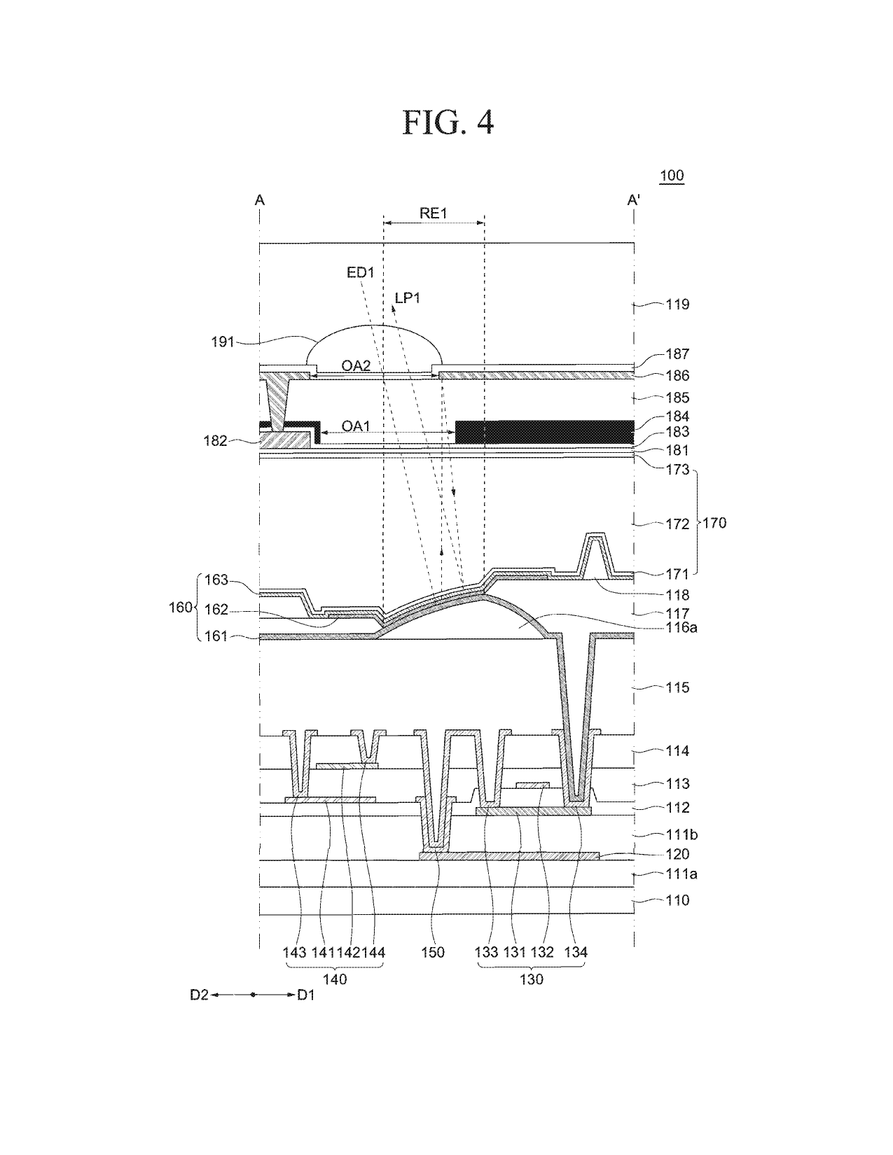

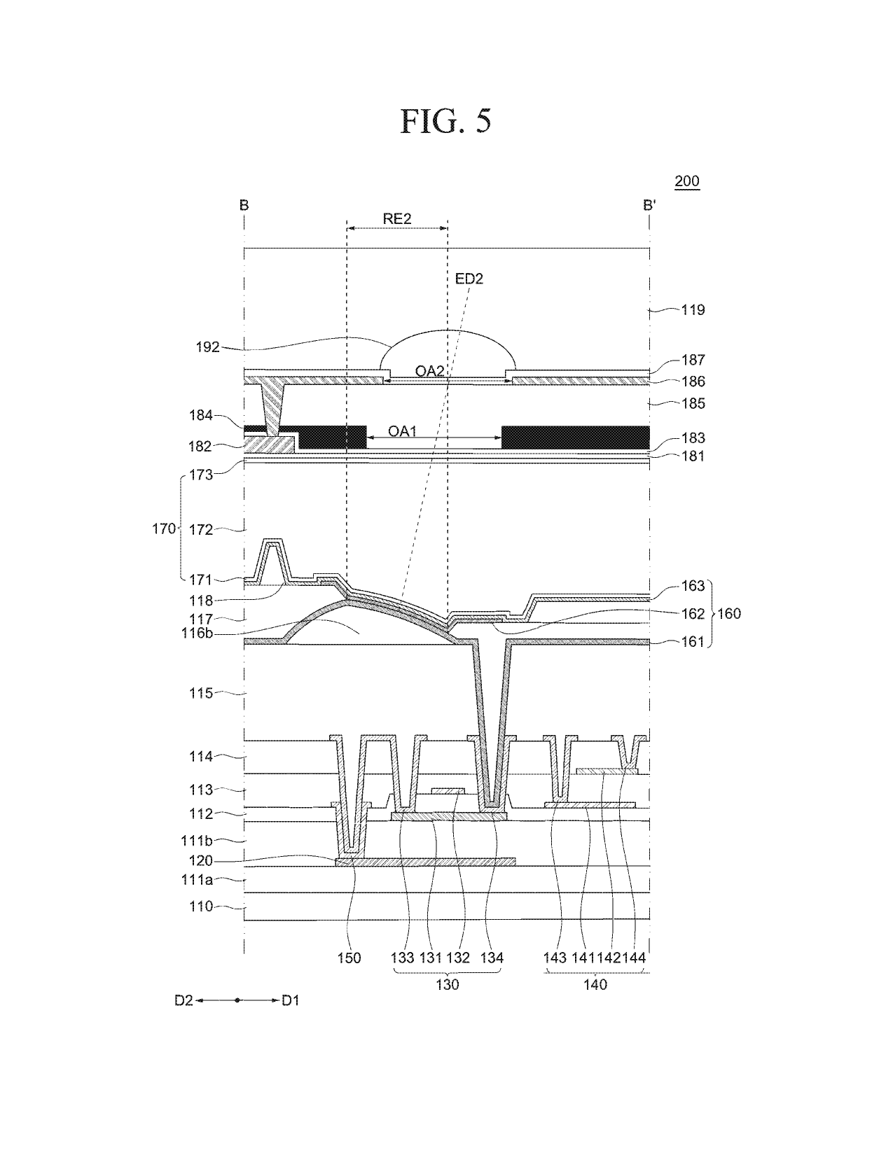

FIG. 3 is an enlarged plan view illustrating an arrangement of sub-pixels according to an embodiment of the invention. FIG. 4 is a cross-sectional view taken along line A-A' of the display device of FIG. 3. FIG. 5 is a cross-sectional view taken along line B-B' of the display device of FIG. 3.

In addition, FIG. 3 illustrates a plane of the pixel PX when the pixel PX includes three sub-pixels, for example, a first sub-pixel RSP, a second sub-pixel GSP, and a third sub-pixel BSP, but embodiments of the invention are not limited thereto. For example, the pixel PX may further include four or more sub-pixels and may be arranged in various types in other embodiments.

FIG. 4 illustrates a pixel of the display device 100 taken along line A-A’ of FIG. 3, in which the first group of light emitting elements G1 is disposed according to an embodiment of the invention. FIG. 5 illustrates a pixel of the display device 100 taken along line B-B’ of FIG. 3, in which the second group of light emitting elements G2 is disposed according to an embodiment of the invention.

Referring to FIG. 3, the pixel PX may include a plurality of sub-pixels SP representing different colors. For example, the pixel PX may include a first sub-pixel RSP configured to implement red, a second sub-pixel GSP configured to implement green, and a third sub-pixel BSP configured to implement blue. According to an embodiment of the invention, the first sub-pixel RSP may be referred to as a red sub-pixel, the second sub-pixel GSP may be referred to as a green sub-pixel, and the third sub-pixel BSP may be referred to as a blue sub-pixel.

The display device 100 may be implemented as a dual view display that displays different images according to a viewing angle. For example, when the display device 100 is included in the vehicle, the display device 100 may display different images to a driver sitting in a driver's seat and a passenger sitting in a passenger seat, without being limited thereto. Hereinafter, the display device 100 will be described with reference to a dual view display, but embodiments of the invention are not limited thereto. In some embodiments, the display device 100 may be implemented to display three or more images depending on the viewing angle. The display device may also be referred to as a multi-view display.

As the display device 100 is capable of displaying different images according to the viewing angle, each of the plurality of sub-pixels SP may include a plurality of light emitting elements providing different viewing angles.

For example, the first sub-pixel RSP may include the first group of light emitting elements G1 in which the first emission area RE1 overlaps the first optical member 191 and the center of the first emission area RE1 is shifted in the first direction D1 based on the center of the first optical member 191. In addition, the first sub-pixel RSP may include the second group of light emitting elements G2 in which the second emission area RE2 overlaps the second optical member 192 and the center of the second emission area RE2 is shifted in the second direction D2 with respect to the center of the second optical member 192.

Likewise, the second sub-pixel GSP may include the first group of light emitting elements G1 in which the center of the first emission area GE1 is shifted in the first direction D1 with respect to the center of the first optical member 191, and the second group of light emitting elements G2 in which the center of the second emission area GE2 is shifted in the second direction D2 with respect to the center of the second optical member 192.

Further, the third sub-pixel BSP may include the first group of light emitting elements G1 in which the center of the first emission area BE1 is shifted in the first direction D1 with respect to the center of the first optical member 191, and the second group of light emitting elements G2 in which the center of the second emission area BE2 is shifted in the second direction D2 with respect to the center of the second optical member 192.

In an embodiment of the invention, the first direction D1 and the second direction D2 may be opposite to each other. For example, the first direction D1 may be a right direction with respect to FIG. 3, for example, a direction toward the front passenger seat of the vehicle. In addition, the second direction D2 may be a left direction with respect to FIG. 3, for example, a direction toward the driver's seat of the vehicle. However, embodiments of the invention are not limited thereto.

The first group of light emitting element G1 may provide an image at a viewing angle in the second direction D2. For example, the first group of light emitting elements G1 may emit light toward the second direction D2. In general, when the first group of light emitting element G1 is driven, the image may be visually recognized by a viewer located in the second direction D2, for example, a driver sitting in the driver's seat of the vehicle.

Further, the second group of light emitting element G2 may provide an image at a viewing angle in the first direction D1. For example, the second group of light emitting elements G2 may emit light in the first direction D1. In general, when the second group of light emitting element G2 is driven, the image may be visually recognized by a viewer located in the first direction D1, for example, a passenger sitting in the passenger seat of the vehicle.

The first group of light emitting element G1 and the second group of light emitting element G2 may be disposed in different rows on a plane. The first group of light emitting elements G1 and the second group of light emitting elements G2 may be alternately disposed in the third direction D3 on a plane. For example, in FIG. 3, the first group of light emitting elements G1 may be disposed in the first row, and the second group of light emitting elements G2 may be disposed in the second row. In addition, the first group of light emitting elements G1 may be disposed in the third row again, and the second group of light emitting elements G2 may be disposed in the fourth row. However, embodiments are not limited thereto.

In one embodiment, the third direction D3 may be a direction intersecting the first direction D1 and the second direction D2, for example, a direction orthogonal to the first direction D1 and the second direction D2. The first direction D1 and the second direction D2 may be a horizontal direction on a plane and the third direction D3 may be a vertical direction. However, embodiments of the invention are not limited thereto.

In each of the plurality of sub-pixels SP, the first optical member 191 overlapping the first emission area RE1 and the second optical member 192 overlapping the second emission area RE2 may be located diagonally to each other with respect to the third direction D3. Therefore, the first optical member 191 and the second optical member 192 may be disposed in a zigzag pattern in the third direction D3.

Hereinafter, in the display device 100 according to an embodiment of the invention, an area in which the first group of light emitting elements G1 of the first sub-pixel RSP is disposed will be described with reference to FIGS. 3 and 4. However, an area in which the first group of light emitting elements G1 is disposed in the second sub-pixel GSP and the third sub-pixel BSP may also be implemented in the same manner as an area in which the first group of light emitting elements are disposed in the first sub-pixel RSP.

Referring to FIGS. 3 and 4, the display device 100 according to an embodiment of the invention may include a substrate 110, a first buffer layer 111a, a light shielding layer 120, a second buffer layer 111b, a transistor 130, a first planarization layer 115, a first protrusion 116a, a plurality of light emitting elements 160, an encapsulation part 170, a touch buffer layer 181, a conductive pattern 182, a first touch insulating layer 183, a black matrix 184, a second touch insulating layer 185, a barrier layer 186, a third touch insulating layer 187, a first optical member 191, and a protective layer 119.

The substrate 110 may include an insulating material, which may be transparent. For example, the substrate 110 may include glass, plastic, a flexible polymer film, or the like. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer(COC), triacetylcellulose (TAC) film, polyvinyl alcohol (PVA) film, polyimide (PI) film, and polystyrene (PS), without being limited thereto.

The first buffer layer 111a may be disposed on the substrate 110. The first buffer layer 111a may reduce penetration of moisture or impurities through the substrate 110. The first buffer layer 111a may include an inorganic insulating material such as silicon oxide (SiOx) and silicon nitride (SiNx), without being limited thereto. The first buffer layer 111a may have a multilayer structure, for example, a stacked structure of a film made of silicon nitride (SiNx) and a film made of silicon oxide (SiOx), without being limited thereto.

The light shielding layer 120 may be disposed on the first buffer layer 111a. The light shielding layer 120 may be disposed to overlap at least the active layer 131 of the transistor 130. Accordingly, external light incident on the active layer 131 may be blocked. In addition, even though in the drawing, it is illustrated that the light shielding layer 120 is a single layer, the light shielding layer 120 may include a plurality of layers. The light shielding layer 120 may include various conductive materials, such as magnesium (Mg), aluminum (Al), nickel (Ni), chromium (Cr), molybdenum (Mo), tungsten (W), gold (Au), or an alloy thereof.

The second buffer layer 111b may be disposed on the light shielding layer 120. The second buffer layer 111b may protect the transistor 130 from impurities such as alkali ions discharged from the substrate 110. In addition, the second buffer layer 111b may improve adhesion between layers formed on the second buffer layer 111b and the substrate 110. Further, the second buffer layer 111b may include, for example, an inorganic insulating material such as silicon oxide (SiOx) and silicon nitride (SiNx), without being limited thereto. The second buffer layer 111b may have a multilayer structure for example, a stacked structure of a film made of silicon nitride (SiNx) and a film made of silicon oxide (SiOx), without being limited thereto.

The transistor 130 may be disposed on the second buffer layer 111b. The transistor 130 may include an active layer 131, a gate electrode 132, a source electrode 133, and a drain electrode 134. The source electrode and the drain electrode of the transistor are not fixed, but may be interchanged with each other depending on the type of the thin film transistor and the voltage difference applied between the source electrode and the drain electrode. Thus, the source electrode and the drain electrode in the embodiments of the invention may be referred to as first and second electrodes respectively.

The active layer 131 may be disposed on the second buffer layer 111b. The active layer 131 may include an oxide semiconductor material. Alternatively, the active layer 131 may include polycrystalline silicon, without being limited thereto.

A gate insulating layer 112 made of an insulating material may be disposed on the active layer 131. The gate insulating layer 112 may include an insulating material. For example, the gate insulating layer 112 may include an inorganic insulating material such as silicon oxide (SiOx) and silicon nitride (SiNx), without being limited thereto.

The gate electrode 132 may be disposed on the gate insulating layer 112. The gate electrode 132 may be disposed on the active layer 131 to overlap the active layer 131. The gate electrode 132 may include various conductive materials, such as magnesium (Mg), aluminum (Al), nickel (Ni), chromium (Cr), molybdenum (Mo), tungsten (W), gold (Au), or an alloy thereof.

The first interlayer insulating layer 113 and the second interlayer insulating layer 114 may be disposed on the gate electrode 132. Although in FIG. 4 exemplarily illustrates that the top surfaces of the first interlayer insulating layer 113 and the second interlayer insulating layer 114 are formed to be flat, the shapes of the first interlayer insulating layer 113 and the second interlayer insulating layer 114 are not limited thereto. For example, in some embodiments, each of the first interlayer insulating layer 113 and the second interlayer insulating layer 114 may be formed along surfaces of components disposed therebelow. In general, the upper surface of each of the first interlayer insulating layer 113 and the second interlayer insulating layer 114 may include a step formed according to a height difference between the components disposed therebelow. Each of the first interlayer insulating layer 113 and the second interlayer insulating layer 114 may include an insulating material. For example, the first interlayer insulating layer 113 and the second interlayer insulating layer 114 may include an inorganic insulating material such as silicon oxide (SiOx) and silicon nitride (SiNx), without being limited thereto.

The source electrode 133 and the drain electrode 134 may be disposed on the second interlayer insulating layer 114. The source electrode 133 and the drain electrode 134 may be electrically connected to the active layer 131 through contact holes formed in the gate insulating layer 112, the first interlayer insulating layer 113, and the second interlayer insulating layer 114, respectively. For example, the source electrode 133 may be connected to a source region of the active layer 131. Further, the drain electrode 134 may be connected to the drain region of the active layer 131.

In addition, a storage capacitor 140 may be further disposed on the substrate 110. The storage capacitor 140 may include a first capacitor electrode 141, a second capacitor electrode 142, a first metal layer 143, and a second metal layer 144.

A first capacitor electrode 141 may be disposed between the gate insulating layer 112 and the first interlayer insulating layer 113. The first capacitor electrode 141 may be disposed on the same layer as the gate electrode 132. Further, the first capacitor electrode 141 may include the same material as the gate electrode 132, and the first capacitor electrode 141 may be formed by the same process as the gate electrode 132, without being limited thereto.

A second capacitor electrode 142 may be disposed between the first interlayer insulating layer 113 and the second interlayer insulating layer 114. The second capacitor electrode 142 may be disposed on the first capacitor electrode 141 to overlap the first capacitor electrode 141. The second capacitor electrode 142 may include various conductive materials, such as magnesium (Mg), aluminum (Al), nickel (Ni), chromium (Cr), molybdenum (Mo), tungsten (W), gold (Au), or an alloy thereof, without being limited thereto.

A first metal layer 143 and a second metal layer 144 may be further disposed on the second interlayer insulating layer 114. The first metal layer 143 and the second metal layer 144 may be disposed on the same layer as the source electrode 133 and the drain electrode 134. Further, the first metal layer 143 and the second metal layer 144 may include the same material as the source electrode 133 and the drain electrode 134, and the first metal layer 143 and the second metal layer 144 may be formed by the same process as the source electrode 133 and the drain electrode 134.

The first metal layer 143 may be electrically connected to the first capacitor electrode 141 through contact holes formed in the first interlayer insulating layer 113 and the second interlayer insulating layer 114. Further, the second metal layer 144 may be electrically connected to the second capacitor electrode 142 through a contact hole formed in the second interlayer insulating layer 114. The structures of the transistor 130 and the storage capacitor 140 are not limited to those shown in FIG. 3, but may be modified in other embodiments. For example, in some embodiments, the second insulating layer 114 may be omitted, and in this case, the second capacitor electrode 142, the first metal layer 143 as well as the source electrode 133 and the drain electrode 134 may be formed on the same layer, such as the first interlayer insulating layer 113.

In addition, a contact electrode 150 may be further disposed between the gate insulating layer 112 and the first interlayer insulating layer 113. The contact electrode 150 may be disposed on the same layer as the gate electrode 132. Further, the contact electrode 150 may include the same material as the gate electrode 132, and the contact electrode 150 may be formed by the same process as the gate electrode 132, without being limited thereto.

The contact electrode 150 may be in contact with the light shielding layer 120 through a contact hole formed in the gate insulating layer 112 and the second buffer layer 111b. Further, the contact electrode 150 may be in contact with the source electrode 133. Therefore, the source electrode 133 may be electrically connected to the light shielding layer 120 through the contact electrode 150.

A first planarization layer 115 may be disposed on the transistor 130 and the storage capacitor 140. The first planarization layer 115 may be disposed to cover components disposed therebelow. The first planarization layer 115 may include an organic insulating material. For example, the first planarization layer 115 may be made of polyimide, acryl, or benzocyclobutene (BCB)-based resin, without being limited thereto.

A first protrusion 116a may be disposed on the first planarization layer 115. The first protrusion 116a may include at least one inclined surface whose height decreases toward a direction opposite to a direction in which the center of the first emission area RE1 is shifted with respect to the center of the first optical member 191. For example, in the area in which the first group of light emitting elements G1 are disposed, the center of the first emission area RE1 may be shifted in the first direction D1 with respect to the center of the first optical member 191. In this case, the height of at least one inclined surface of the first protrusion 116a may be lowered toward the second direction D2. In other words, the height of at least one inclined surface of the first protrusion 116a may be increased toward the first direction D1. Hereinafter, when a height of a surface is lowered toward a specific direction, it is referred to as that such surface is inclined in the specific direction.

The first protrusion 116a may further include another inclined surface inclined in the first direction D1, without being limited thereto. In one embodiment, referring to FIG. 4, the first protrusion 116a is illustrated as including one inclined surface inclined in the second direction D2 and the other inclined surface inclined in the first direction D1, but embodiments of the invention is not limited thereto. In another embodiment, the first protrusion 116a may not include an inclined surface inclined in the first direction D1.

Further, referring to FIG. 4, it is illustrated that the inclination of one inclined surface, such as the first protrusion 116a inclining in the second direction D2, is different from that of the other inclined surface inclined in the first direction D1, but embodiments of the invention are not limited thereto. For example, the first protrusion 116a may have the same inclination as one inclined surface inclined in the second direction D2 and the other inclined surface inclined in the first direction D1. In general, the first protrusion 116a may be formed to be symmetrical, but embodiments of the invention are not limited thereto.

The first protrusion 116a may include polyimide, acryl, or benzocyclobutene (BCB)-based resin, without being limited thereto. In addition, the first protrusion 116a may include the same material as the first planarization layer 115, without being limited thereto. Referring to FIG. 4, an interface is illustrated between the first protrusion 116a and the first planarization layer 115, but when the first protrusion 116a includes the same material as the first planarization layer 115, an interface may not exist between the first protrusion 116a and the first planarization layer 115. For example, the first protrusion 116a and the first planarization layer 115 may be integrally formed, but embodiments of the invention are not limited thereto.

The light emitting element 160 is disposed on the first planarization layer 115 and the first protrusion 116a. The light emitting element 160 may include a first electrode 161, an emission layer 162, and a second electrode 163.

The first electrode 161 may be disposed on the first planarization layer 115 and the first protrusion 116a. The first electrode 161 may include a conductive material. The first electrode 161 may include a material having a high reflectance. For example, the first electrode 161 may include metal such as aluminum (Al) and silver (Ag), without being limited thereto. The first electrode 161 may have a multilayer structure, for example, a structure in which a reflective electrode made of metal is positioned between transparent electrodes made of a transparent conductive material such as indium tin oxide (ITO) or indium zinc oxide (IZO), without being limited thereto.

The first electrode 161 may be electrically connected to the source electrode 133 or the drain electrode 134 through a contact hole formed in the first planarization layer 115. Referring to FIG. 4, it is illustrated that the first electrode 161 is connected to the drain electrode 134, but it is not limited thereto. Accordingly, the first electrode 161 may be electrically connected to the active layer 131 of the transistor 130 through the source electrode 133 or the drain electrode 134.

The first electrode 161 includes an inclined surface. A height of the inclined surface of the first electrode 161 may decrease in a direction opposite to a direction in which the center of the first emission area RE1 is shifted with respect to the center of the first optical member 191. For example, the first electrode 161 is disposed on the surface of the first protrusion 116a inclined in the second direction D2 so as to form an inclined surface in the second direction D2, however, embodiments of the invention are not limited thereto. The first electrode 161 may be conformally formed on the first protrusion 116a, and the inclined surface of the first electrode 161 and the inclined surface of the first protrusion 116a may correspond to each other and have substantially the same profile or inclination angle.

The inclination angle of the inclined surface inclined in the second direction D2 of the first electrode 161 may be modified according to the viewing angle of the viewer, and the inventive concepts are not limited to a particular inclination angle.

The emission layer 162 is disposed on the first electrode 161. The emission layer 162 may generate light having a luminance corresponding to a voltage difference between the first electrode 161 and the second electrode 163. For example, the emission layer 162 may include an emission material layer (EML) including a light emitting material. The light emitting material may include an organic material, an inorganic material, or a hybrid material, without being limited thereto.

The emission layer 162 may have a multilayer structure. For example, the emission layer 162 may further include at least one of a hole injection layer (HIL), a hole transport layer (HTL), an electron transport layer (ETL), and an electron injection layer (EIL), without being limited thereto.

The second electrode 163 may include a conductive material. The transmittance of the second electrode 163 may be higher than that of the first electrode 161. For example, the second electrode 163 may include a transparent conductive material, such as indium tin oxide (ITO) or indium zinc oxide (IZO), a metal alloy, such as MgAg, or an ytterbium (Yb) alloy, without being limited thereto. In general, light generated by the emission layer 162 may be emitted through the second electrode 163.

A bank 117 which exposes an inclined surface of the first electrode 161 inclined in the second direction D2 is disposed on the first electrode 161. The bank 117 may be disposed to cover an area other than the inclined surface of the first electrode 161 inclined in the second direction D2. Further, the emission layer 162 and the second electrode 163 may be disposed to cover the inclined surface inclined in the second direction D2 exposed by the bank 117. In this case, the emission layer 162 and the second electrode 163 may extend from the inclined surface inclined in the second direction D2 to the upper surface of the bank 117. As described above, the first electrode 161, the emission layer 162, and the second electrode 163 are in contact with each other on an inclined surface inclined in the second direction D2 exposed by the bank 117, such that the first emission area RE1 may be defined.

In addition, the first electrode 161 and the emission layer 162 may be spaced apart from each other between adjacent sub-pixels SP. For example, the first electrodes 161 may be spaced apart from each other between the first sub-pixel RSP and the second sub-pixel GSP adjacent thereto. Further, the first electrodes 161 spaced apart from each other between the first sub-pixel RSP and the second sub-pixel GSP adjacent thereto may be insulated by the bank 117. Further, the first electrodes 161 may be spaced apart from each other between the second sub-pixel GSP and the third sub-pixel BSP adjacent thereto, and the spaced apart first electrodes 161 may be insulated by the bank 117.

Referring to FIG. 4, a height of the top surface of the bank 117 disposed at one end of the first emission area RE1 in the second direction D2 is larger than that of the top surface of the bank 117 disposed at another end of the first emission area RE1 in the first direction D1, so that the light emitted from the first emission area RE1 may not be blocked by the bank 117 disposed at another end of the first emission area RE1. Although it is illustrated that the height of the bank 117 disposed at opposite ends of the first emission area RE1 are different from each other, embodiments of the invention are not limited thereto. In some embodiments, the height of the upper surface of the bank 117 may be the same.

The bank 117 may include an insulating material such as an organic insulating material. For example, the bank 117 may be made of polyimide, acryl, or benzocyclobutene (BCB)-based resin, and the bank 117 may include a material different from the first planarization layer 115, without being limited thereto. Alternatively, the bank 117 may include an inorganic insulating material such as silicon nitride, aluminum nitride, zirconium nitride, titanium nitride, hafnium nitride, tantalum nitride, silicon oxide, aluminum oxide, or titanium oxide, without being limited thereto. Further, the bank 117 may be configured by a black bank with a high light absorption rate to prevent or reduce color mixture between adjacent sub-pixels.

A spacer 118 may be disposed on the bank 117. The spacer 118 is a layer for maintaining a predetermined distance between the deposition mask and the bank 117 to prevent or reduce damage caused by contact with the deposition mask. As in the bank 117, the spacer 118 may be made of polyimide resin, acrylic resin, or benzocyclobutene (BCB) resin, without being limited thereto. Referring to FIG. 4, it is illustrated that the bank 117 and the spacer 118 are separate configurations, but embodiments of the invention are not limited thereto. For example, in some embodiments, the bank 117 and the spacer 118 may be integrally and simultaneously formed in one process.

The encapsulation part 170 may be disposed on the light emitting element 160. The encapsulation part 170 may have a multilayer structure. For example, the encapsulation part 170 may include a first encapsulation layer 171, a second encapsulation layer 172, and a third encapsulation layer 173 that are sequentially stacked, without being limited thereto.

The first encapsulation layer 171 may be disposed on the light emitting element 160. The first encapsulation layer 171 is disposed on the light emitting element 160 to suppress the penetration of moisture or oxygen into the light emitting element 160. The first encapsulation layer 171 may be made of an inorganic material such as silicon oxide (SiOx), silicon nitride (SiNx), silicon oxynitride (SiNxOy), or aluminum oxide (AlyOz), without being limited thereto.

The second encapsulation layer 172 may be disposed on the first encapsulation layer 171 to planarize the surface thereof. In addition, the second encapsulation layer 172 may cover foreign substances or particles that may be generated during the manufacturing process. The second encapsulation layer 172 may be made of an organic material, for example, silicon oxycarbon (SiOxCz), acrylic or epoxy-based resin, without being limited thereto.

The third encapsulation layer 173 may be disposed on the second encapsulation layer 172 to suppress penetration of moisture or oxygen, as the first encapsulation layer 171. In this case, the third encapsulation layer 173 and the first encapsulation layer 171 may be formed to seal the second encapsulation layer 172. In general, moisture or oxygen permeating into the light emitting element 160 may be more effectively reduced by the third encapsulation layer 173. The third encapsulation layer 173 may include an inorganic material such as silicon oxide (SiOx), silicon nitride (SiNx), silicon oxynitride (SiNxOy), or aluminum oxide (AlyOz), without being thereto. A thickness difference due to the light emitting element 160 may be mitigated by the second encapsulation layer 172. For example, an upper surface of the second encapsulation layer 172 opposite to the substrate 110 may be substantially flat.

A touch buffer layer 181 may be disposed on the encapsulation part 170. The touch buffer layer 181 may be disposed between the encapsulation part 170 and the conductive pattern 182 and may be configured to insulate the conductive pattern 182. For example, the touch buffer layer 181 may include an insulating material such as an organic insulating material or an inorganic insulating material, without being limited thereto.

A conductive pattern 182 may be disposed on the touch buffer layer 181. The conductive pattern 182 may be electrically connected to touch electrodes disposed on the second touch insulating layer 185, without being limited thereto. Alternatively, separately from the conductive pattern 182, a touch bridge electrode connected to touch electrodes, which may be disposed on the second touch insulating layer 185, may be further disposed. In this case, the conductive pattern 182 may be disposed on the same layer as the touch bridge electrode. Further, the conductive pattern 182 may include the same material as the touch bridge electrode. For example, the conductive pattern 182 may include a metal material such as titanium (Ti), aluminum (Al), silver (Ag), copper (Cu), and a magnesium-silver alloy (Mg:Ag), without being limited thereto.

The first touch insulating layer 183 may be disposed on the conductive pattern 182. The first touch insulating layer 183 may be disposed between the conductive pattern 182 and the black matrix 184 to insulate the conductive pattern 182.

The first touch insulating layer 183 may include an insulating material. For example, the first touch insulating layer 183 may include an organic insulating material or an inorganic insulating material, without being limited thereto.

The black matrix 184 is disposed on the first touch insulating layer 183. The black matrix 184 may be disposed between the plurality of sub-pixels SP to reduce a color mixture of the plurality of sub-pixels SP. As such, the black matrix 184 may be disposed to overlap the bank 117.

The black matrix 184 includes a plurality of first openings OA1 exposing at least a portion of the first emission area RE1. In an embodiment, the number of the first opening OA1 may correspond to the number of the first emission areas RE1, without being limited thereto.

One end of the first opening OA1 may further protrude to the inside of the first emission area RE1 than one end of the first emission area RE1. Accordingly, a part of the black matrix 184 may overlap the first emission area RE1. Further, the other end of the first opening OA1 may not overlap the first emission area RE1. Accordingly, the other end of the first opening OA1 may be disposed outward of the first emission area RE1. The other end of the first opening OA1 may be arranged in the second direction D2 with respect to the one end of the first opening OA1. For example, the center of the first emission area RE1 may be shifted in the first direction D1 with respect to the center of the first opening OA1.

The second touch insulating layer 185 may be disposed on the black matrix 184. The second touch insulating layer 185 may be disposed between the black matrix 184 and the barrier layer 186 to insulate the barrier layer 186.

The second touch insulating layer 185 may include an insulating material. For example, the second touch insulating layer 185 may include an organic insulating material or an inorganic insulating material, without being limited thereto.

The barrier layer 186 is disposed on the second touch insulating layer 185. The barrier layer 186 may be disposed to overlap the bank 117 and the black matrix 184. The barrier layer 186 may include an opaque metal material. In an embodiment, the barrier layer 186 may limit a path of light generated by the light emitting element 160. For example, the barrier layer 186 may block light traveling in the lateral direction among light emitted from the first emission area RE1. In this case, the barrier layer 186 may also be referred to as a view control layer or a view control pattern.

The barrier layer 186 may include a plurality of second openings OA2 overlapping the first opening OA1 of the black matrix 184. In this case, one end of the second opening OA2 may protrude further toward the center of the first optical member 191 than one end of the first opening OA1. Accordingly, at least a portion of the barrier layer 186 may overlap the first emission area RE1. For example, the center of the first opening OA1 may be shifted in the first direction D1 with respect to the center of the second opening OA2. The size of the first opening OA1 may be equal to or greater than that of the second opening OA2.

The barrier layer 186 may include metal material such as titanium (Ti), aluminum (Al), silver (Ag), copper (Cu), and a magnesium-silver alloy (Mg:Ag), without being limited thereto.

A touch electrode may be further disposed on the second touch insulating layer 185. The touch electrode may be configured to sense an external touch input using a user's finger or a touch pen.

The barrier layer 186 may be disposed on the same layer as the touch electrode. Further, the barrier layer 186 may include the same material as the touch electrode, without being limited thereto.

A third touch insulating layer 187 may be disposed on the barrier layer 186. The third touch insulating layer 187 may be disposed between the barrier layer 186 and the first optical member 191 to insulate the barrier layer 186.

A plurality of first optical members 191 are disposed on the third touch insulating layer 187 and overlap the plurality of second openings OA2 of the barrier layer 186. For example, the first optical member 191 may be disposed to cover an edge of the barrier layer 186, without being limited thereto.

Referring to FIGS. 3 and 4 together, the first optical member 191 may limit a traveling direction of light which passes through the first optical member 191 in the first direction D1 and/or the third direction D3. For example, a planar shape of the first optical member 190 may be circular. However, embodiments of the inventions are not limited thereto, and the planar shape of the first optical member 191 positioned in each sub-pixel RSP, GSP, BSP may have a polygonal shape or an oval shape.

The center of the first optical member 191 may not coincide with the center of the first emission area RE1. For example, the center of the first emission area RE1 may be shifted in the first direction D1 with respect to the center of the first optical member 191. In an embodiment, the inclined surface of the first emission area RE1 may be inclined toward the second direction D2, and in this case, the content or images provided by the first emission area RE1 may be provided in the second direction D2.

A protective layer 119 may be disposed on the first optical member 191. The protective layer 119 may include an insulating material. For example, the protective layer 119 may include an organic insulating material, without being limited thereto.

An area in which the second group of light emitting elements G2 of the first sub-pixel RSP is disposed in the display device 100 according an embodiment of the invention will be described with reference to FIG. 5. In an embodiment, an area in which the second group of light emitting elements G2 is disposed in the second sub-pixel GSP and the third sub-pixel BSP may have substantially the same configuration.

In particular, a configuration of the second protrusion 116b is different only in the area in which the second group of light emitting element G2 of the first sub-pixel RSP is disposed from the area in which the first group of light emitting element G1 is disposed, and all other configurations are the same as the area in which the first group of light emitting element G1 is disposed. Accordingly, redundant descriptions thereof will be omitted.

Referring to FIG. 5, in an area in which the second group of light emitting element G2 is disposed, the second protrusion 116b may be disposed on the first planarization layer 115. The second protrusion 116b may include at least one inclined surface inclined toward the first direction D1. For example, the height of at least one inclined surface may decrease in the first direction D1.

The second protrusion 116b may further include another inclined surface inclined in the second direction D2, without being limited thereto. In FIG. 5, the second protrusion 116b according to an embodiment is illustrated as including one inclined surface inclined in the first direction D1 and the other inclined surface inclined in the second direction D2. However, embodiments are not limited thereto, and the second protrusion 116b may not include an inclined surface inclined in the second direction D2 in some embodiments.

Further, FIG. 5 illustrates that the inclination of one inclined surface of the second protrusion 116b in the first direction D1 is different from the inclination of the other inclined surface thereof in the second direction D2. However, embodiments are not limited thereto, and in some embodiments, the second protrusion 116b may have the same inclination as one inclined surface inclined in the first direction D1 and the other inclined surface inclined in the second direction D2. In an embodiment, the second protrusion 116b may be formed to be symmetrical, without being limited thereto.

The second protrusion 116b may be made of polyimide, acryl, or benzocyclobutene (BCB)-based resin, without being limited thereto. In addition, the second protrusion 116b may be made of the same material as the first planarization layer 115, without being limited thereto. Referring to FIG. 5, an interface is illustrated between the second protrusion 116b and the first planarization layer 115, but when the second protrusion 116b includes the same material as the first planarization layer 115, an interface may not exist between the second protrusion 116b and the first planarization layer 115. For example, the second protrusion 116b and the first planarization layer 115 may be integrally formed, without being limited thereto.

The light emitting element 160 is disposed on the first planarization layer 115 and the second protrusion 116b. In the second group of light emitting element G2, the light emitting element 160 is different from the first group of light emitting element G1 only in the direction in which the second emission area RE2 is inclined and the relative positional relationship with the second optical member 192, and other configurations are substantially the same. As such, redundant descriptions will be omitted or briefly provided.

The first electrode 161 is disposed on the first planarization layer 115 and the second protrusion 116b. In this case, the first electrode 161 includes an inclined surface inclined in the first direction D1. For example, the first electrode 161 is disposed on the inclined surface inclined in the first direction D1 of the second protrusion 116b to form an inclined surface inclined in the first direction D1.

The inclination angle of the inclined surface of the first electrode 161 in the first direction D1 may be modified according to the viewing angle of the viewer, however, embodiments of the invention are not limited thereto.

The emission layer 162 and the second electrode 163 may be disposed on the first electrode 161.

In the area in which the second group of light emitting elements G2 are disposed, the bank 117 is disposed to expose an inclined surface of the first electrode 161 inclined in the first direction D1. The bank 117 may be disposed to cover an area other than the inclined surface of the first electrode 161 inclined in the first direction D1. Further, the emission layer 162 and the second electrode 163 may be disposed to cover the inclined surface inclined in the first direction D1 exposed by the bank 117. In this case, the emission layer 162 and the second electrode 163 may extend from the inclined surface inclined in the first direction D1 to the upper surface of the bank 117. As described above, the first electrode 161, the emission layer 162, and the second electrode 163 are in contact with each other on an inclined surface inclined in the first direction D1 exposed by the bank 117, such that the second emission area RE2 may be defined.

FIG. 5 illustrates that the heights of the top surfaces of the bank 117 disposed at opposing ends of the second emission area RE2 may be different from each other. However, embodiments of the invention are not limited thereto, and the height of the upper surface of the bank 117 may be the same in other embodiments.

In the area in which the second group of light emitting elements G2 are disposed, a plurality of second optical members 192 may be disposed on the third touch insulating layer 187 so as to overlap the plurality of second openings OA2 of the barrier layer 186. For example, the second optical member 192 may be disposed to cover an edge of the barrier layer 186, without being limited thereto.

Referring to FIGS. 3 and 5 together, the second optical member 192 may limit a traveling direction of light which passes through the second optical member 192 to the first direction D1 and/or the third direction D3. For example, a planar shape of the second optical member 192 may be circular. However, embodiments of the invention are not limited thereto, and the planar shape of the second optical member 192 positioned in each of the subpixels RSP, GSP, and BSP may have a polygonal shape or an elliptical shape.

The center of the second optical member 192 may not coincide with the center of the second emission area RE2. For example, the center of the second emission area RE2 may be shifted in the second direction D2 with respect to the center of the second optical member 192. In an embodiment, the inclined surface of the second emission area RE2 may be inclined toward the first direction D1, and in this case, the content or images provided by the second emission area RE2 may be provided in the first direction D1.

In addition, when the display device is disposed on at least a part of the dashboard of the vehicle, content may be provided to a user, such as a driver or a passenger. In this case, when different content is provided to the driver and the passenger from one display device, because positions of the driver and the passenger are different from each other, the displayed content would need to be provided at different viewing angles. As such, as one method for providing content at different viewing angles in one display device, the center of the emission area may be shifted in different directions based on the center of the optical member. However, the luminance distribution of the emission area tends to decrease symmetrically left and right around the center, and when the emission area is shifted in a direction different from the center of the optical member, the maximum luminance may be lowered than when the center of the optical member and the center of the emission area coincide.

In an embodiment, the display device 100 includes a light emitting element in which the emission area is inclined in the viewing angle direction of the viewer, so that the direction toward the emission area and the viewing angle direction of the viewer may coincide.

Referring to FIG. 4, the display device 100 according to an embodiment of the invention may include the first emission area RE1 having an inclined surface inclined in the second direction D2. In an embodiment, the direction ED1 facing the first emission area RE1 may also be inclined in the second direction D2, and the viewing angle of the user watching in the second direction D2 may coincide with the direction ED1 facing the first emission area RE1. Further, for example, with reference to FIG. 5, the display device 100 according to an embodiment of the invention may include the second emission area RE2 having inclined surface inclined in the first direction D1. In an embodiment, the direction ED2 facing the second emission area RE2 may be inclined in the first direction D1, and the viewing angle of the user watching in the first direction D1 may coincide with the direction ED2 facing the second emission area RE2.

As described above, the display device 100 according to embodiments of the invention includes the first emission area RE1 and the second emission area RE2 inclined in different directions to provide a dual view that provides different images to respective viewers located in different directions.

In addition, in the display device 100 according to an embodiment of the invention, an inclined surface is formed in the emission area so that the viewing angle of each user and the direction in which the emission area faces coincide, and thus the maximum luminance at each viewing angle of the user other than the front of the display device 100 may be improved. Accordingly, all users can visually recognize higher quality content according to each viewing angle.

Further, as in the display device 100 according to an embodiment of the invention, when the emission area includes an inclined surface, light emitted from the emission area is reflected back to the emission area by the barrier layer 186. When the light is reflected back to the emission area, the maximum luminance according to the viewing angle may be improved by reflecting it back to the viewing angle direction of the viewer. Referring to FIG. 4, one end of the barrier layer 186 on the first emission area RE1 may further protrude to the inside of the first emission area RE1 than the black matrix 184. As such, a part LP1 of light emitted from the first emission area RE1 may be reflected back toward the first emission area RE1 by the barrier layer 186. In addition, the reflected light LP1 may pass through the area formed by the protruding length difference between the barrier layer 186 and the black matrix 184 and reach the first emission area RE1 again. The barrier layer 186 is formed on the same layer as the touch electrodes, and thus may be formed as a portion of the touch electrodes, or may be formed as an island shape spaced apart from the touch electrodes. Further, the light LP1 reflected to the first emission area RE1 by the inclination angle of the first emission area RE1 may be reflected again in the direction ED1 in which the first emission area RE1 faces. In this manner above, the display device 100 according to an embodiment of the invention may further expand the generation area of the reflected light. Accordingly, the traveling direction of a larger amount of light may be changed to the viewing angle direction of the viewer, so that the maximum luminance at a desired viewing angle may be improved.

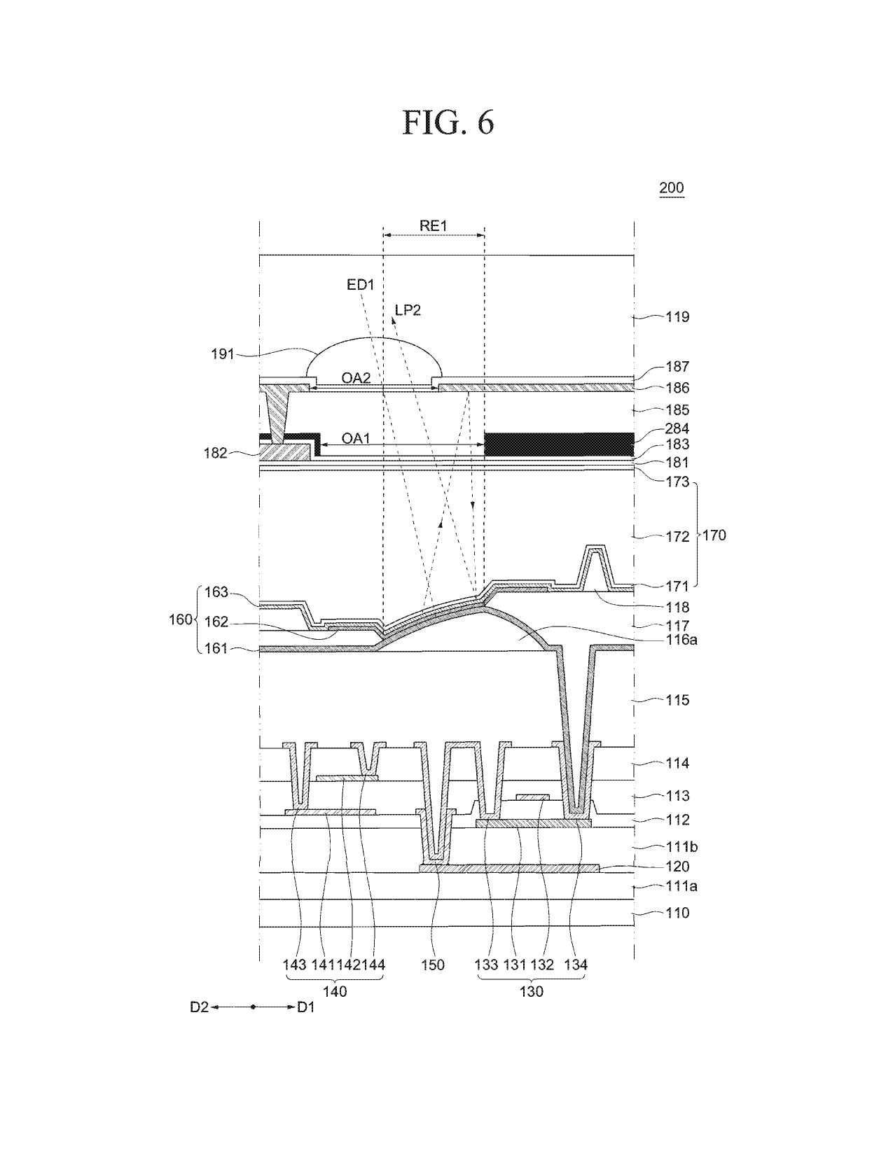

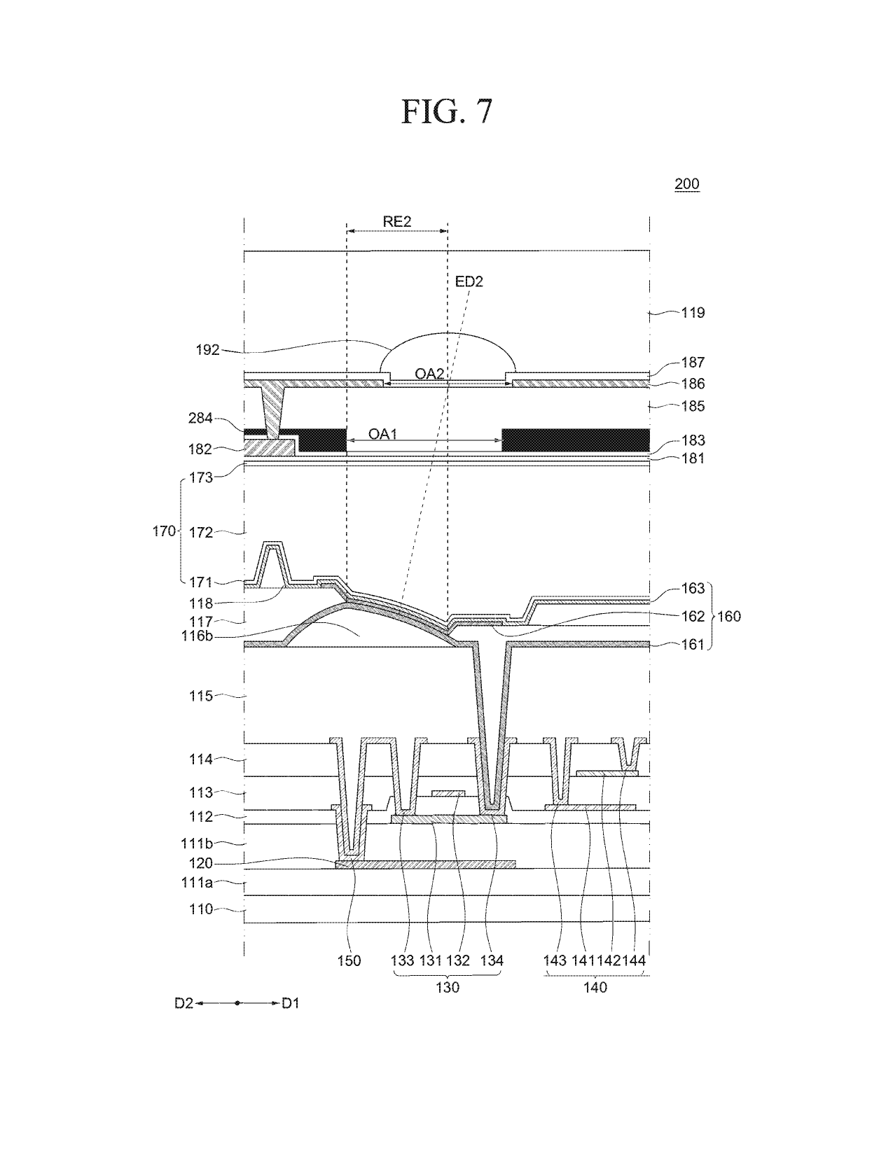

FIG. 6 is a cross-sectional view of a display device according to an embodiment of the invention. FIG. 7 is a cross-sectional view of a display device according to another embodiment of the invention.

FIG. 6 is a cross-sectional view of an area corresponding to FIG. 4, and FIG. 7 is a cross-sectional view of an area corresponding to FIG. 5 according to another embodiments. The only difference between a display device 200 of FIGS. 6 and 7 and the display device 100 of FIGS. 1 to 5 is a black matrix 284, but other components are substantially the same. As such, redundant descriptions will be omitted.

Referring to FIGS. 6 and 7, a black matrix 284 is disposed on the first touch insulating layer 183. In some embodiments, the black matrix 284 may be disposed to overlap the bank 117.

The black matrix 284 includes a plurality of first openings OA1 exposing at least a portion of the first emission area RE1 and the second emission area RE2. In an embodiment, the number of the first opening OA1 may correspond to the number of the first emission area RE1 and the second emission area RE2.

One end of the first opening OA1 may coincide with or align with one end of the first emission area RE1 and one end of the second emission area RE2, respectively. For example, referring to FIG. 6, one end of the bank 117 disposed at an upper end of the first protrusion 116a and one end of the first opening OA1 may be positioned on the same line extending in the thickness direction, which intersects the first and second directions D1 and D2. The other end of the first opening OA1 may be disposed outside the first emission area RE1 more than the other end of the bank 117 disposed at the lower end of the first protrusion 116a.

Referring to FIG. 7, one end of the bank 117 disposed at an upper end of the second protrusion 116b and one end of the first opening OA1 may be positioned on the same line extending in the thickness direction . The other end of the first opening OA1 may be disposed outside the second emission area RE2 more than the other end of the bank 117 disposed at the lower end of the second protrusion 116b.

Accordingly, the first emission area RE1 and the second emission area RE2 may not overlap the black matrix 284, respectively, in the thickness direction of the display device.

The display device 200 according to an embodiment of the invention includes a light emitting element in which the emission area is inclined toward the viewing angle of the viewer so that the direction in which the emission area is directed may match the viewing angle direction of the viewer.

Referring to FIG. 6, the display device 200 according to an embodiment of the invention may include an inclined surface in which the first emission area RE1 is inclined in the second direction D2. Accordingly, the viewing angle of the user viewing the content in the second direction D2 may match the direction ED1 in which the first emission area RE1 faces. Further, referring to FIG. 7, as an example, the display device 200 according to an embodiment of the invention may include an inclined surface in which the second emission area RE2 is inclined in the first direction D1. Accordingly, the viewing angle of the user watching in the first direction D1 may coincide with the direction ED2 in which the second emission area RE2 faces.

As described above, the display device 200 according to an embodiment of the invention includes the first emission area RE1 and the second emission area RE2 inclined in different directions to provide a dual view that provides different images to respective viewers located in different directions.

In addition, in the display device 200 according to an embodiment of the invention, an inclined surface is formed in the emission area such that the viewing angle of each user and the direction in which the emission area faces coincide, and therefore the maximum luminance at each viewing angle of the user other than the front of the display device 200 may be improved. Accordingly, all users can visually recognize higher quality content according to each viewing angle.

Further, in the display device 200 according to an embodiment of the invention, the first opening OA1 may be extended such that one end of the first opening OA1 of the black matrix 284 is aligned with one end of the first emission area RE1 and/or the second emission area RE2. In an embodiment, when light emitted from the first emission area RE1 and the second emission area RE2 is reflected by the barrier layer 186 and returns to the first emission area RE1 and the second emission area RE2, absorption by the black matrix 284 may be more effectively prevented or reduced.

Referring to FIG. 6, a part LP2 of light emitted from the first emission area RE1 may be directed to the barrier layer 186 located thereabove. Further, the light which reaches the barrier layer 186 is reflected from the lower surface of the barrier layer 186 to pass through the first opening OA1 and then propagate toward the first emission area RE1. For example, in the display device 200 according to an embodiment of the invention, as the first opening OA1 is further expanded, a greater amount of light, among light reflected from the barrier layer 186, may pass through the first opening OA1. Accordingly, a larger amount of light may be reflected again in the first emission area RE1 to travel toward the first optical member 191. As described above, in the display device 200 according to another embodiment of the invention, the traveling direction of more light may be changed to the viewing angle direction of the viewer, so that the maximum luminance at a desired viewing angle may be further improved.

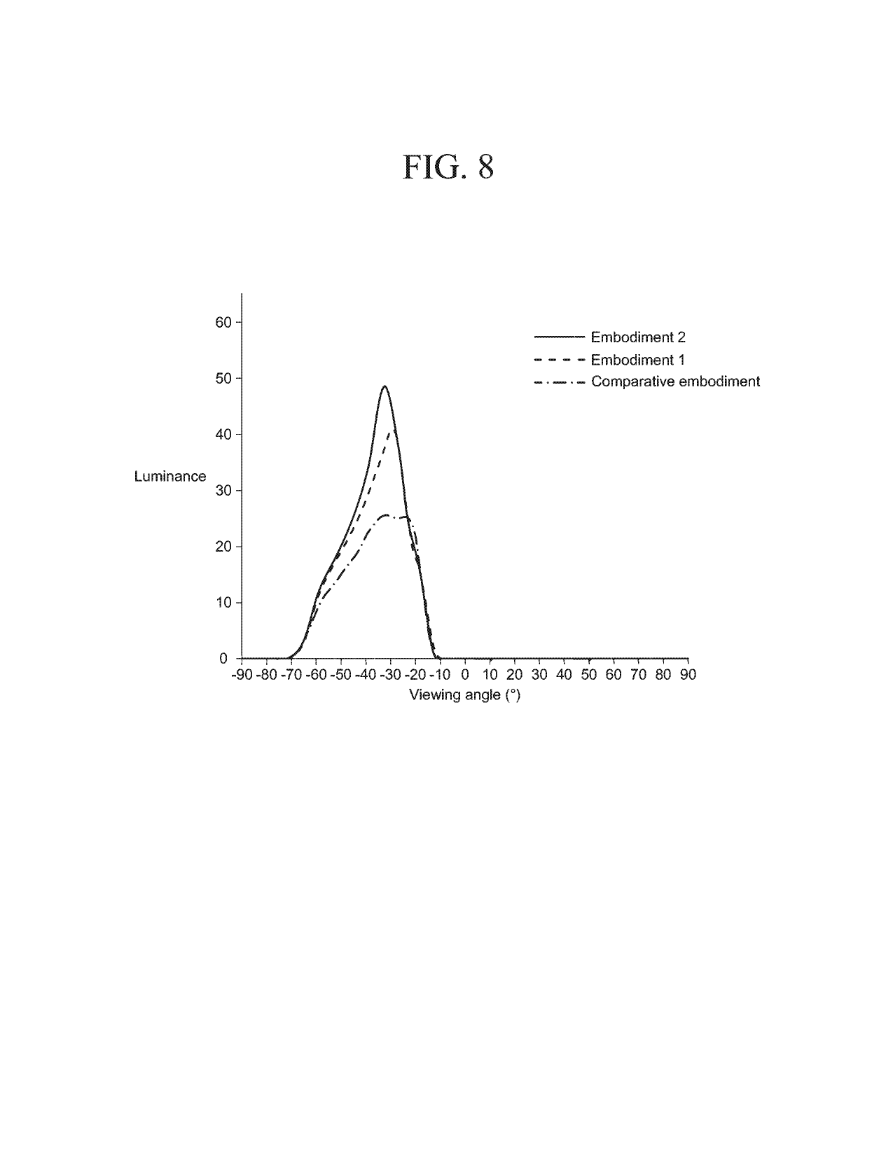

Hereinafter, a maximum luminance change according to a viewing angle of the display device 100 according to an embodiment of the invention and the display device 200 according to another embodiment of the invention will be described in more detail with reference to FIG. 8.

FIG. 8 is a simulation result of comparing luminance changes according to a viewing angle of comparative examples and embodiments of the invention.

In FIG. 8, Embodiment 1 is a case in which the first emission area RE1 is disposed to be biased in the first direction D1 based on the first optical member 191 and inclined in the second direction D2, as described with reference to FIG. 4 among the display devices 100 according to an embodiment of the invention described with reference to FIGS. 1-5. In this case, the inclination angle of the emission area RE1 is set to 7° with respect to the substrate 110. Further, in Embodiment 1, one end of the first opening OA1 of the black matrix 184 protrudes further toward the inside of the first emission area RE1 than one end of the bank 117 located above the first protrusion 116a. In Embodiment 2, as described with reference to FIG. 6 among the display devices 200 according to another embodiment of the invention, the first emission area RE1 is disposed to be inclined in the first direction D1 with respect to the first optical member 191 and is inclined in the second direction D2. In this case, the inclination angle of the first emission area RE1 is set to 7° with respect to the substrate 110. In addition, in Embodiment 2, one end of the bank 117 disposed above the first protrusion 116a and one end of the first opening OA1 of the black matrix 284 are positioned on the same line. In the comparative example, compared to Example 1, the emission area is not inclined and is disposed parallel to the substrate.

In FIG. 8, the X-axis denotes a viewing angle (°), and the left side based on the viewing angle of 0° refers to a change in the viewing angle in the second direction D2, and the right side thereof refers to a change in the viewing angle in the first direction D1. The Y-axis denotes a luminance value.

Referring to FIG. 8, it is confirmed that Example 1 in which luminance at a viewing angle of about 30° in the second direction D2 is inclined in the second direction D2 is significantly improved compared to Comparative Example. This indicates that when the user visually recognizes an image from the side where the emission area is disposed to be inclined in the direction in which the user is located, the luminance value emitted in the direction in which the user is located increases. For example, when the user visually recognizes an image from one side of the display device, a higher quality image may be visually recognized.

In addition, in the case of Embodiment 2, in which one end of the first opening OA1 of the black matrix 284 coincides with one end of the bank 117, it may be seen that the luminance value at the same viewing angle is further improved than in Embodiment 1, in which one end of the first opening OA1 of the black matrix 184 protrudes to the inside of the first emission area RE1 from one end of the bank 117. This indicates that by extending the first opening of the black matrix to the end of the bank, the path of more light is changed to face the first optical member 191. Accordingly, when the user visually recognizes an image from one side of the display device, the user may visually recognize a higher quality image.

According to embodiments of the invention, deterioration in luminance, which may occur as the viewing angle changes, may be prevented or reduced.

According to embodiments of the invention, the luminous efficiency at an intended viewing angle may be improved.

According to embodiments of the invention, images may be displayed at different viewing angles, and for example, luminous efficiency may be improved at different viewing angles.

According to embodiments of the invention, as the luminous efficiency is improved, the display device may be driven with lower power.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a substrate;
a light emitting element disposed on the substrate and including a first electrode having an inclined surface, a light emitting layer, and a second electrode;
a bank disposed on the first electrode and exposing the inclined surface to define an emission area of the light emitting element;
a black matrix disposed on the bank and including a first opening at least partially overlapping the emission area;
a barrier layer disposed on the black matrix and including a second opening at least partially overlapping the first opening; and
an optical member disposed on the second opening.

2. The display device of claim 1, wherein the center of the emission area is shifted in a first direction with respect to the center of the optical member.

3. The display device of claim 2, wherein a height of the inclined surface decreases toward a second direction opposite to the first direction.

4. The display device of claim 1, wherein one end of the first opening protrudes from one end of the emission area toward the inside of the emission area.

5. The display device of claim 4, wherein one end of the second opening protrudes further toward the center of the optical member than the one end of the first opening.

6. The display device of claim 1, wherein one end of the first opening coincides with one end of the emission area.

7. The display device of claim 5, wherein one end of the second opening protrudes further toward the center of the optical member than the one end of the first opening.

8. The display device of claim 1, further comprising:
a planarization layer disposed on the substrate; and
a protrusion disposed on the planarization layer,
wherein the emission area is disposed on the protrusion.

9. The display device of claim 1, wherein the barrier layer includes an opaque metal material.

10. The display device of claim 1, wherein a size of the first opening is equal to or greater than that of the second opening.

11. A display device, comprising:
a substrate;
a plurality of light emitting elements disposed on the substrate and each including an emission area having an inclined surface;
a black matrix disposed on the plurality of light emitting elements and including a plurality of first openings corresponding to the emission areas of the plurality of light emitting elements;
a barrier layer disposed on the black matrix and including a plurality of second openings at least partially overlapping the plurality of first openings; and
a plurality of optical members disposed on the plurality of second openings,
wherein the plurality of light emitting elements includes:
a first group of light emitting elements having the inclined surface inclined in a second direction; and
a second group of light emitting elements having the inclined surface inclined in a first direction different from the second direction.

12. The display device of claim 11, wherein the first direction and the second direction are opposite to each other.

13. The display device of claim 11, wherein a center of each of the first group of light emitting elements is shifted in the first direction with respect to a center of a corresponding optical member among the plurality of optical members, and
a center of each of the second group of light emitting elements is shifted in the second direction with respect to a center of a corresponding optical member among the plurality of optical members.

14. The display device of claim 11, wherein the first group of light emitting elements and the second group of light emitting elements are alternately disposed in a third direction orthogonal to the first direction on a plane.

15. The display device of claim 14, wherein the plurality of optical members includes a first optical member at least partially overlapping the first group of light emitting element and a second optical member at least partially overlapping the second group of light emitting element, and
the first optical member and the second optical member are disposed in a zigzag pattern in the third direction.

16. The display device of claim 11, further comprising:
a planarization layer disposed on the substrate; and
a plurality of protrusions disposed on the planarization layer,
wherein emission areas of the plurality of light emitting elements are disposed on the plurality of protrusions.

17. The display device of claim 11, wherein one end of the plurality of second openings protrudes further toward the center of the plurality of optical members than one end of the plurality of first openings.

18. The display device of claim 11, wherein one end of the plurality of first openings coincides with one end of the emission area.

19. The display device of claim 11, wherein one end of the plurality of first openings protrudes to the inside of the emission area.

20. A display device comprising:
a substrate;
a light emitting element disposed on the substrate and including a first electrode having an inclined surface, a light emitting layer, and a second electrode;
a bank disposed on the first electrode and exposing the inclined surface to define an emission area of the light emitting element; and
an optical member disposed over the bank and at least partially overlapping the emission area,
wherein the center of the emission area is shifted in a first direction with respect to the center of the optical member, and
wherein a height of the inclined surface decreases toward a second direction opposite to the first direction.
